(19) United States
(12) Patent Application Publication
(10) Pub. No.: US 2012/0282742 A1
(43) Pub. Date: Nov. 8, 2012

(54) SEMICONDUCTOR DEVICE AND METHOD FOR MANUFACTURING THE SAME

(75) Inventors: Koichi Matsuda, Kawasaki-shi (JP); Ryo Hayashi, Yokohama-shi (JP); Shinji Kodaira, Kawasaki-shi (JP)

(73) Assignee: CANON KABUSHIKI KAISHA, Tokyo (JP)

(21) Appl. No.: 13/551,038

(22) Filed: Jul. 17, 2012

Related U.S. Application Data
(63) Continuation-in-part of application No. 13/046,564, filed on Mar. 11, 2011.

(30) Foreign Application Priority Data
Mar. 15, 2010 (JP) 2010-057728
Feb. 15, 2011 (JP) 2011-029998
Jul. 20, 2011 (JP) 2011-159076

(51) Int. Cl. H01L 21/336

(52) U.S. Cl. 438/151; 257/E21.412

(57) ABSTRACT

A method for manufacturing a silicon semiconductor device includes the steps of diluting a silicon-containing raw material gas with hydrogen gas by a factor equal to or larger than 600, applying radiofrequency power to a gas mixture of the diluted raw material gas and hydrogen gas to induce electric discharge, depositing silicon out of the raw material gas decomposed by the electric discharge onto a substrate, and controlling the pressure of the gas mixture to be equal to or higher than 600 Pa. The power density Pw(W/cm²) of the radiofrequency power is specified in such a manner that the value Pw(W/cm²)*D/P(Pa) should fall within the range of 0.083 to 0.222, both inclusive, where D represents the dilution factor between the raw material gas and hydrogen gas and P (Pa) represents the pressure of the gas mixture.

### CROSS-REFERENCE TO RELATED APPLICATION

This is a continuation-in-part application of U.S. patent application Ser. No. 13/046,564 filed on Mar. 11, 2011, now pending, which claims priority to Japanese Patent Application No. 2010-057728 filed Mar. 15, 2010, No. 2011-029998 filed Feb. 15, 2011, and No. 2011-159076 filed Jul. 20, 2011, the contents of all of which are hereby incorporated by reference herein in their entirety.

### BACKGROUND OF THE INVENTION

1. Field of the Invention

The present invention relates to a semiconductor device having a crystalline silicon active layer and a method for manufacturing such a semiconductor device.

2. Description of the Related Art

Active-matrix display apparatuses have long been known which contain thin-film semiconductors for picture element driving. Thin-film transistors (TFT) for this type of display apparatus are required to be not only capable of driving picture elements but also highly durable. This is because direct-current operation of TFTs can cause a threshold voltage shift and thereby lead to varying characteristics and nonuniform luminance of the TFTs.

Active elements for display apparatuses are based on thin-film silicon semiconductors. Examples of silicon thin films used for this purpose include amorphous silicon films, microcrystalline silicon films, and polycrystalline silicon films.

TFTs having an amorphous silicon active layer can be easily formed to have a large area and manufactured at low cost, but they are not resistant to stress caused by electrical current and thus their threshold voltage drifts during a prolonged flow of current. TFTs having a polycrystalline silicon active layer are better in terms of the driving capability and electric current stress resistance, but their manufacturing process involves laser annealing and ion doping for crystallization, increasing the manufacturing cost.

TFTs having a microcrystalline silicon active layer are manufactured in a process similar to that for amorphous silicon TFTs and thus can be produced at low cost. However, they contain smaller crystal grains than those in polycrystalline silicon films and thus are of lower carrier mobility than TFTs based on polycrystalline silicon. In some cases, their resistance to electrical current stress may be close to that of polycrystalline silicon TFTs; however, it is not always high because the degree of crystallinity and the diameter of crystal grains vary depending on the manufacturing conditions.

For microcrystalline silicon TFTs, various attempts have been made to increase the degree of crystallinity of the active layer, the layer for the formation of the channel, and thereby to improve their driving capability and durability. An effective arrangement of the film formation conditions for the active layer has been found, in which the dilution factor between the silicon-containing raw material gas and the diluent gas (hydrogen, argon, or the like) is set large, or in other words the ratio of quantity between the diluent gas and the raw material gas is set high. U.S. Pat. No. 5,796,116 describes a method for forming a microcrystalline silicon layer, in which crystal cores are formed with the hydrogen dilution factor (SiH₄ to H₂) set at 200 or larger.

However, an increased dilution factor leads to a slowed film formation speed and thus results in a reduced manufacturing throughput and an increased manufacturing cost. The same publication mentions a possible process for forming the silicon film, in which the dilution factor is high until the film has a thickness of 10 nm on the gate insulating layer and is reduced thereafter.

Japanese Patent Laid-Open No. 2008-124392 discloses a bottom-gate (inverted-staggered) TFT. This TFT is composed of a high-crystallinity semiconductor layer, a contact layer, and an intermediate layer or layers sandwiched between them, such as a buffer semiconductor layer, a low-crystallinity semiconductor layer, a semiconductor layer with variable crystallinity, and/or other layers; this TFT is a semiconductor device with a linear crystallinity gradient. This publication specifies a film formation pressure and a hydrogen dilution factor in describing the production conditions of each semiconductor layer.

Recommended ranges of silicon-related parameters can also be seen in U.S. Pat. No. 7,833,885. This publication proposes a method of forming a microcrystalline silicon-containing film under the following conditions: the dilution factor between the raw material gas and hydrogen, 500 to 3000; the relative flow rate of argon gas, 5% to 40%; pressure, ≧3 Torr. This publication also states that the formed plasma is maintained by applying a radiofrequency (RF) power density of 0.2 W/cm² to 0.8 W/cm².

As with TFTs having an amorphous silicon active layer, microcrystalline silicon TFTs also experience threshold voltage drifts. This appears to be because of the presence of amorphous silicon near the channel. The microcrystalline silicon film does not always have a microcrystalline structure in its entire volume; when it is formed on an insulator such as silicon oxide or silicon nitride, a hybrid film containing silicon crystal grains and amorphous silicon appears early in the film formation process. For bottom-gate transistors, in which the channel is formed near the interface between the gate insulating layer and the silicon film formed on it, it is an important requirement that the amorphous silicon content should be minimized near the interface.

When a microcrystalline silicon film is formed by chemical vapour deposition (CVD), the amorphous content can be reduced by increasing the dilution factor of the raw material gas. In addition to controlling the dilution factor in this way, adjustment of the gas pressure and the RF power for plasma generation also contributes to a reduced amorphous content and an increased degree of crystallinity.

However, even if the RF power is set to its optimum value, the optimum RF power setting varies depending on the dilution factor and the gas pressure. This means that different combinations of a dilution factor and a gas pressure have different optimum RF power values.

### SUMMARY OF THE INVENTION

The present invention provides a method for manufacturing a microcrystalline silicon TFT highly resistant to stress caused by electrical current. In this method, the optimum range of RF power can be easily determined from the given dilution factor and the given gas pressure in accordance with the relation we found among these three parameters. The resulting microcrystalline silicon TFT thus has great resistance to electrical current stress.

More specifically, the present invention provides a method for manufacturing a silicon semiconductor device including steps of:

forming a gate electrode and a gate insulating layer containing silicon nitride on a substrate in this order;

forming a silicon-oxide-containing layer on the gate insulating layer;

forming a silicon layer containing crystalline silicon and amorphous silicon by chemical vapour deposition on the silicon-oxide-containing layer; and

forming a contact layer and source and drain electrodes on the silicon layer in this order,

wherein the chemical vapour deposition in the step of forming the silicon layer is performed under a condition of

a power density Pw of the radiofrequency power being in the range of 0.1 to 0.8 W/cm²,

a pressure P of a gas mixture in a chemical vapour deposition chamber being in the range of 200 to 1066 Pa and a dilution factor D of a silicon-containing raw material gas with a hydrogen gas being in the range of 100 to 3000.

The present invention also provides a method for manufacturing a silicon semiconductor device including steps of:

forming a gate electrode and a gate insulating layer containing silicon nitride on a substrate in this order;

forming a silicon layer containing crystalline silicon and amorphous silicon by chemical vapour deposition; and

forming a contact layer and source and drain electrodes on the silicon layer in this order,

wherein the chemical vapour deposition in the step of forming a silicon layer is performed by steps of:

diluting a silicon-containing raw material gas with a hydrogen gas by a factor equal to or larger than 600;

applying radiofrequency power to a gas mixture of the diluted raw material gas and hydrogen gas to induce electric discharge;

depositing silicon out of the raw material gas decomposed by the electric discharge onto a substrate; and

controlling a pressure of the gas mixture to be equal to or higher than 600 Pa,

wherein the power density Pw(W/cm²) of the radiofrequency power is specified in such a manner that the value Pw(W/cm²)*D/P (Pa) should fall within the range of 0.083 to 0.222, both inclusive, where D represents the dilution factor of the raw material gas with the hydrogen gas and P (Pa) represents the pressure of the gas mixture.

The present invention, in which the power density is set to be in its optimum range determined by the dilution factor and the gas pressure, allows for precise tuning of film formation conditions. The resulting microcrystalline silicon film thus has a high degree of crystallinity even in a portion near the gate insulating layer of a bottom-gate TFT, or even in the region for the formation of the channel of the TFT, thereby making the TFT less likely to change its threshold voltage on exposure to electrical current stress.

Further features of the present invention will become apparent from the following description of exemplary embodiments with reference to the attached drawings.

### BRIEF DESCRIPTION OF THE DRAWINGS

FIG. 1 schematically illustrates the structure of an RF plasma CVD apparatus.

FIG. 2 schematically illustrates the structure of a sheet-fed manufacturing apparatus for the production of TFTs.

FIG. 3 is a cross-sectional view of a bottom-gate TFT.

FIG. 4 presents the measured threshold voltage drift plotted against the dilution factor.

FIG. 5 presents the measured threshold voltage drift plotted against the pressure.

FIG. 6 presents the measured threshold voltage drift plotted against the power density for two dilution factors.

FIG. 7 is a graph for explaining the formation process of a microcrystalline silicon film.

FIG. 8 is a graph for explaining the formation speed of a microcrystalline silicon film.

### DESCRIPTION OF THE EMBODIMENTS

### 1. Method for Manufacturing a TFT

The present invention uses chemical vapour deposition (CVD) to form a silicon film as a component of a TFT. A typical process for forming a silicon-based or other semiconductor thin films on a glass substrate is RF plasma CVD. In the RF plasma CVD process, a gas as the raw material of the semiconductor thin film is introduced into a film-forming chamber, radiofrequency (RF) power is applied to induce electric discharge and generate a plasma. The ions released inside the plasma react with each other, and the reaction product accumulates on the substrate and forms a thin film. In order to obtain a silicon thin film, a raw material gas containing silicon atoms, e.g., silane (SiH₄), is diluted with hydrogen (H₂), argon (Ar), or a similar diluent and introduced into a film-forming chamber, the raw material gas is decomposed in a plasma, and silicon is deposited out of the decomposed raw material gas onto a substrate.

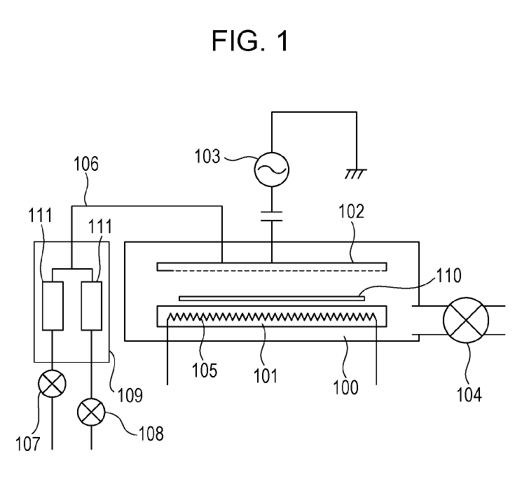

The structure of an RF plasma CVD apparatus is schematically illustrated in FIG. 1.

The film-forming chamber 100 contains an anode 101 and a cathode 102 for generating a plasma by electric discharge. These electrodes are arranged to face each other and supplied with RF-frequency (13.6 MHz) alternating current power from a power source 103. The substrate 110 is placed on the anode 101 and heated by a heater 105.

The heating temperature is set to a suitable value depending on the formation conditions of the semiconductor film. However, when a microcrystalline silicon film is intended, the heating temperature is usually in the range of 100° C. to 300° C., both inclusive, and preferably in the range of 150° C. to 250° C., both inclusive, on the substrate temperature basis.

The raw material gas and the diluent gas flow through gas supply valves 107 and 108 and are introduced into a mixing box 109 and mixed. Mass flow controllers 111 supporting the control of gas flow rates are used to regulate the flow rates of the gases. The obtained gas mixture is sent through piping 106 to the film-forming chamber 100 and exposed inside the film-forming chamber 100 to electric discharge to generate a plasma. The generated ions react with each other, and the reaction product accumulates on the substrate 110. Any unreacted portion of the gas is emitted out through a valve 104.

The piping 106 supplies the mixture gas to the hollow cathode 102. The cathode 102 has a gas ejection nozzle or nozzles formed on the anode 101 side, through which the gas mixture is ejected. A plurality of gas ejection nozzles can be formed and they can be located at equal distances from the joint with the piping 106 if possible. This arrangement ensures that the material ejected from the cathode 102 forms a uniform film.

Additionally, the cathode 102 is larger in area than the substrate 110 and its shape is suitably chosen so that the microcrystalline silicon film formed on the substrate 110 should be uniform.

In the apparatus illustrated in FIG. 1, the dilution factor can be adjusted by changing the ratio between the flow rates of the mass flow controllers 111. The RF power is adjusted by changing the output of the power supply 103, and the pressure of the gas mixture in the film-forming chamber 100 is regulated using the valve 104.

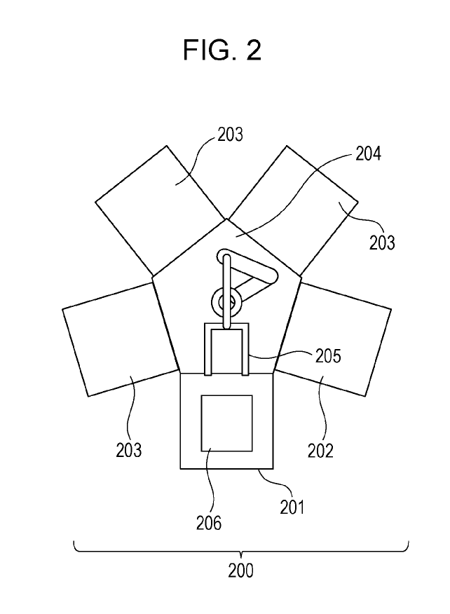

FIG. 2 schematically illustrates the structure of a sheet-fed CVD apparatus for manufacturing transistors and other semiconductor devices.

The sheet-fed CVD apparatus 200 has a load lock chamber 201, a heating chamber 202, and three film-forming chambers 203, and the entire apparatus 200 is placed in a vacuum environment. Each of the film-forming chambers 203 has the same structure as that illustrated in FIG. 1, but the kind and number of gases supplied thereto vary depending on the kind of film formed therein, i.e., a silicon film, a gate insulating film, and others. A substrate 206 is conveyed by an arm mechanism 205 to enter and leave these chambers one by one, and thereby films are sequentially formed.

### 2. Structure of a TFT

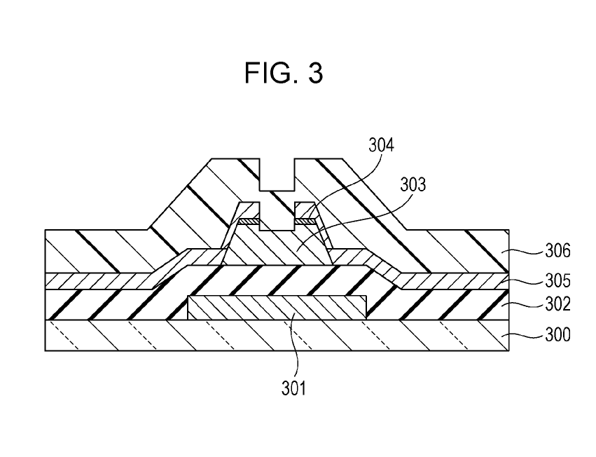

A cross-section of a bottom-gate thin-film transistor (TFT) is illustrated in FIG. 3.

A substrate 300 is patterned with a gate electrode 301, which faces an active layer 303, a microcrystalline silicon film, across a gate insulating layer 302. The active layer 303 is connected to source and drain electrodes 305 via an ohmic contact layer 304; therefore, the channel is formed between these two electrodes through a portion of the active layer 303 on the gate insulating layer 302 side. The whole TFT is covered with a passivation layer 306.

Structures different from that illustrated in FIG. 3 are also possible. For example, the TFT may contain a silicon nitride film, a silicon oxide film, or a laminate of silicon nitride and silicon oxide films formed as an etching stopper layer on the surface of the active layer 303 opposite to the channel.

The substrate 300 of the TFT is made of high-melting glass, quartz, ceramics, or any other appropriate material. The material of the gate electrode 301 is molybdenum (Mo), titanium (Ti), tungsten (W), nickel (Ni), tantalum (Ta), copper (Cu), aluminum (Al), or an alloy of them, and this electrode is formed as film by sputtering, vacuum vapour deposition, or any other appropriate method. In addition, the gate electrode 301 may be formed by layering several metal coatings.

After being patterned with the gate electrode 301, the substrate 300 is transferred into such an RF plasma CVD apparatus as that illustrated in FIG. 2. Then, the gate insulating layer 302, the active layer 303, and the contact layer 304 are sequentially formed.

The gate insulating layer 302 can be a silicon nitride film; however, it may be a silicon oxide film, a laminate of silicon oxide and silicon nitride films, or a silicon oxide-nitride film. If a laminate of silicon oxide and silicon nitride films is used, the film on the active layer 303 side can be made of silicon nitride. Silicon nitride can be synthesized out of a suitable gas mixture containing SiH₄, ammonia (NH₃), nitrogen (N₂), H₂, and so forth, and silicon oxide can be synthesized out of a suitable gas mixture containing SiH₄, nitrous oxide (N₂O), tetraethoxisilane (TEOS), oxygen (O₂), and so forth.

The thickness of the gate insulating layer 302 can be in the range of 50 to 300 nm.

Prior to the formation of the microcrystalline silicon active layer 303 on the gate insulating layer 302, the surface of the gate insulating layer 302 may be treated for improved contact in the interface between the two layers. Surface treatment for this purpose can be performed by various methods, including the formation of a silicon oxide film on the gate insulating layer 302, surface oxidation by exposing the gate insulating layer 302 to an O₂ atmosphere, and so forth.

As for the active layer 303, which is made of microcrystalline silicon, the raw material gas can be SiH₄. The diluent gas can be H₂ gas.

After the formation of the active layer 303, an impurity semiconductor film is formed in the same film-forming chamber to provide the contact layer 304. The contact layer 304 may be amorphous or crystalline as long as it is heavily doped with an n-type impurity. This contact layer 304 is formed for the purpose of providing ohmic contact between the active layer 303 and the metal layer that will later be shaped into the source and drain electrodes 305, and its thickness is in the range of 10 to 300 nm and preferably in the range of 20 to 100 nm.

After the formation of the contact layer 304, the substrate 206 (see FIG. 2) is placed in the load lock chamber 201 and taken out. Then, a metal layer is formed on the contact layer 304 and photolithographically shaped into source and drain electrodes 305, and the portion of the contact layer 304 facing the gate across the channel is removed. The metal layer used to form the source and drain electrodes 305 is a monolayer of Mo, Ti, W, Ni, Ta, Cu, Al, or an alloy of them or a laminate formed as an appropriate combination of monolayers of these materials.

The substrate 206 is then returned to the sheet-fed CVD apparatus 200, and a silicon nitride passivation layer 306 is formed to complete the TFT. This TFT can serve as a component of a display apparatus after a contact hole is formed through the passivation layer 306 and a display panel is connected to the hole.

### 3. Results of Tests on Film Formation Conditions

The characteristics of a silicon film obtained by plasma CVD are mainly determined by the following three film formation conditions: (1) the dilution factor D of the silicon-containing raw material gas, (2) the gas pressure P (Pa) in the film-forming chamber, and (3) the density Pw(W/cm²) of the RF alternating current power for continuous electric discharge.

The present inventors prepared microcrystalline silicon films with different sets of the conditions (1) to (3) to identify the conditions under which a film could be obtained with a small threshold voltage drift. The following describes the procedure used and the results obtained.

First, the common base laminate, on which all the microcrystalline silicon films were formed regardless of the formation conditions used, was prepared as follows.

A gate electrode 301 was formed on a base glass substrate 300 by depositing Mo by RF sputtering to a thickness of 100 nm, and shaped into a predefined pattern. The workpiece was then placed in a film-forming chamber 203 of a CVD apparatus, and a gate insulating layer 302 was formed by deposition in accordance with the arrangement specified in Table 1, namely Gate Insulating Layer Formation Conditions, to a thickness of 200 nm.

TABLE 1

| | | |
|---|---|---|
| Power density | 0.37 | W/cm² |
| Pressure | 170 | Pa |
| Film thickness | 200 | nm |
| SiH₄ | 100 | sccm |
| NH₃ | 1000 | sccm |
| N₂ | 3000 | sccm |

The power density Pw(W/cm²) is determined by dividing the output power (W) of the power source 103 by the area (cm²) over which the anode 101 and the cathode 102 face each other.

Subsequently, the workpiece was exposed to an O₂ atmosphere to oxidize the surface of the gate insulating layer 302. The conditions used are listed in Table 2.

TABLE 2

| | | |
|---|---|---|
| Temperature | 300° | C. |
| Pressure | 133 | Pa |
| O₂ gas | 1000 | sccm |
| Exposure time | 120 | seconds |

### (1) Dilution Factor

Several pieces of the common base laminate were prepared by the above procedure, and microcrystalline silicon films were formed on them with a fixed pressure, a fixed power density, and different dilution factors of the raw material gas. The conditions used are listed in Table 3. SiH₄ gas was diluted with H₂ by factors from 200 to 1000.

TABLE 3

| | | |
|---|---|---|
| Temperature | 200° | C. |
| Pressure | 1200 | Pa |
| Power density | 0.27 | W/cm² |

| | |
|---|---|
| Dilution factor | 200 to 1000 |

The dilution factor was defined as the ratio of the H₂ flow rate to the SiH₄ flow rate. Several dilution factors within the range specified in Table 3 were achieved by changing the SiH₄ flow rate with respect to a fixed H₂ flow rate. Thus, high dilution factors represent small SiH₄ flow rates. Note that since the dilution factor was as high as at least 200, the pressure was regarded as dependent almost solely on the H₂ flow rate and constant regardless of dilution factor.

After a microcrystalline silicon film as the active layer 303 was formed using the specified dilution factor, a contact layer 304 and source and drain electrodes 305 were formed on it by plasma CVD and RF magnetron sputtering, respectively, and then shaped into a predefined pattern by dry etching.

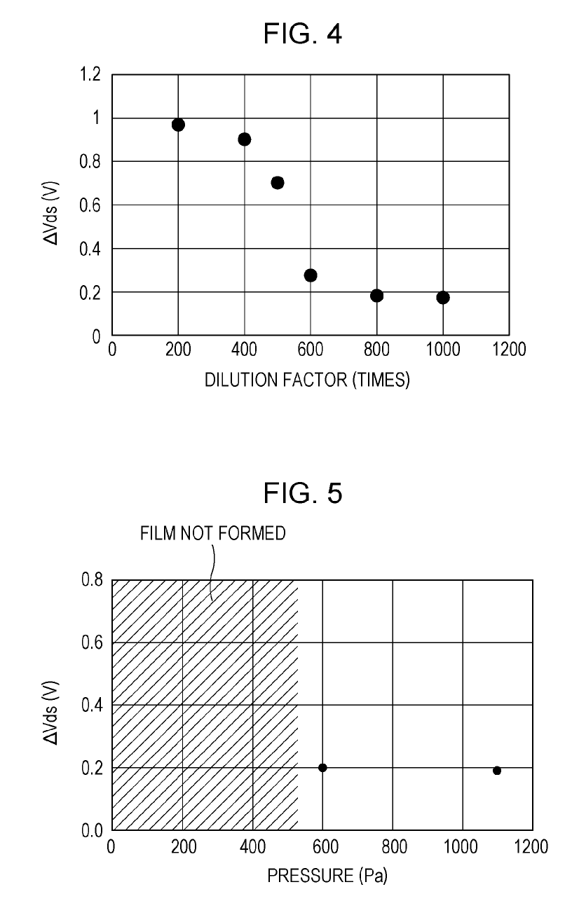

TFTs prepared by the above procedure were subjected to the measurement of the resistance to electric current stress. Results are shown in FIG. 4. The measurement apparatus was Agilent 4155C Semiconductor Parameter Analyzer, and the sample stage was maintained at 25° C. during measurement. The assessment of stress resistance was performed by supplying the TFT with a continuous flow of a drain electric current Id of 0.1 μA with Vd=Vg=0 V and normalization for W/L=1 and measuring the change in Vds from baseline to a certain time point. Hereinafter, this change in Vds is referred to as the threshold voltage drift and denoted by ΔVds. The acceptance criterion for the threshold voltage drift ΔVds is <0.3 V at a time point of 150 hours.

Dilution factors smaller than 600 resulted in ΔVds values after 150 hours of electric current stress exceeding the acceptance limit, 0.3 V, whereas dilution factors of 600 and higher resulted in ΔVds values smaller than 0.3 V. A higher dilution factor resulted in a lower ΔVds value, probably because of a reduced amorphous silicon content and an increased crystalline silicon content.

### (2) Pressure

Subsequently, microcrystalline silicon films were formed with a fixed power density, a fixed dilution factor, and different pressures in the range of 300 to 1100 Pa. The conditions used are listed in Table 4. The common base laminate was used for all, the raw material gas was SiH₄, and the diluent gas was H₂.

TABLE 4

| | | |
|---|---|---|
| Temperature | 200° | C. |
| Pressure | 300 to 1100 | Pa |
| Power density | 0.10 | W/cm² |

| | |
|---|---|
| Dilution factor | 1000 |

In the same way as in (1), TFTs were prepared containing the obtained microcrystalline silicon films and were assessed for the resistance to electric current stress.

Results are shown in FIG. 5. Pressures of 600 Pa and higher resulted in ΔVds values smaller than 0.3 V, whereas pressures lower than 600 Pa resulted in a failure to form the film, suggesting that the film etching speed increases with decreasing pressure.

### (3) Power Density

Microcrystalline silicon films were formed with the fixed pressure and dilution factor specified in Table 5 and different power densities in the range of 0.067 to 0.267 W/cm². The common base laminate was used for all, and the raw material gas and the diluent gas were of the same kind as in (1) and (2).

TABLE 5

| | | |
|---|---|---|
| Temperature | 200° | C. |
| Pressure | 1000 | Pa |
| Power density | 0.067 to 0.267 | W/cm² |

| | |
|---|---|
| Dilution factor | 1000 |

Subsequently, another set of microcrystalline silicon films were formed with the dilution factor of Table 5 reduced to 600, the range of power density changed to 0.077 to 0.400 W/cm², and the pressure unchanged. The conditions used are listed in Table 6. The common base laminate was used for all, and the raw material gas and the diluent gas were of the same kind as in (1) and (2).

TABLE 6

| | | |
|---|---|---|
| Temperature | 200° | C. |
| Pressure | 1000 | Pa |
| Power density | 0.077 to 0.400 | W/cm² |

| | |
|---|---|
| Dilution factor | 600 |

In the same way as in (1) and (2), TFTs were prepared containing the microcrystalline silicon films formed under the conditions of Tables 5 and 6 and were assessed for the resistance to electric current stress.

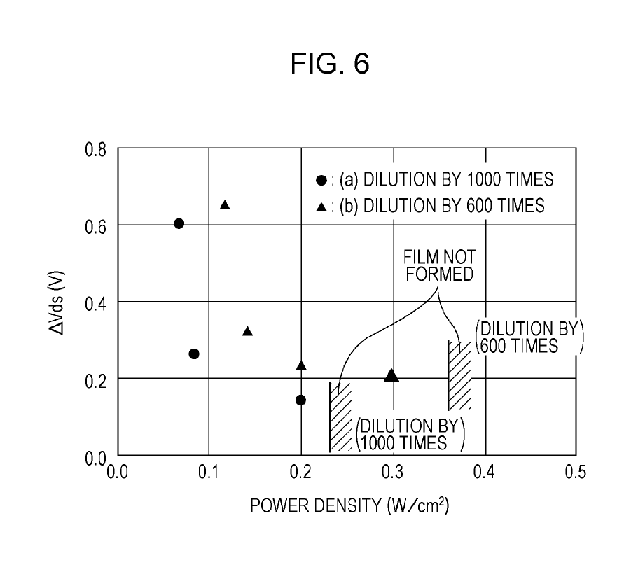

Results are shown in FIG. 6. In FIG. 6, the horizontal axis represents the power density, and the vertical axis represents the threshold voltage drift. The black circles are for a dilution factor of 1000 (a), and the black triangles are for a dilution factor of 600 (b).

Low power densities resulted in larger threshold voltage drifts regardless of whether the dilution factor was large or small; however, the larger dilution factor resulted in an extended lower limit of power density above which the threshold voltage drift could remain low. On the other hand, too high power densities resulted in a failure to form the film.

When the dilution factor was set at 1000, the microcrystalline silicon films obtained with RF power densities of 0.083 W/cm² and higher showed ΔVds values smaller than 0.3 V even after 150 hours of exposure to electric current stress, whereas that obtained with an RF power density of 0.077 W/cm² exhibited a large threshold voltage drift because of an increased amorphous silicon content.

High power densities of 0.222 W/cm² and higher resulted in a failure to form the microcrystalline silicon film. This is probably because the enhanced etching effect of H₂ inhibited the formation of the silicon film. It was therefore found that film formation conditions with too high a power density were also unsuitable.

In case (b), a dilution factor of 600, power densities of 0.140 W/cm² and higher resulted in ΔVds values after 150 hours of electric current stress smaller than 0.3 V, and RF power settings of 0.367 W/cm² and higher resulted in a failure to form the crystalline silicon film.

As can be seen from the above, the formation of a silicon film with a satisfactorily low threshold voltage drift requires a power density set within a particular range; the power density should not be too low or too high for a good silicon film to be formed. Furthermore, the appropriate range of power density varies depending on the dilution factor; both its upper and lower limits shift downward with decreasing dilution factor.

The optimum range of power density Pw was determined to be 0.083 W/cm²≦Pw≦0.222 W/cm² for (a) dilution by 1000 times, and 0.140 W/cm²≦Pw≦0.367 W/cm² for (b) dilution by 600 times.

The upper and lower limits of the optimum range of power density depend on the dilution factor D. Thus, the above relations can be transformed using the product of the power density Pw(W/cm²) multiplied by dilution factor D into a single relation for both (a) and (b): 83≦Pw*D≦222. This relation can further be converted as follows by division by the pressure P (Pa), which is 1000 Pa in this instance: 0.083≦Pw*D/P≦0.222. The meaning of the quantity Pw*D/P will be described later in this specification.

### 4. Film Formation Process

The general perception of the formation process of a microcrystalline silicon film is as follows.

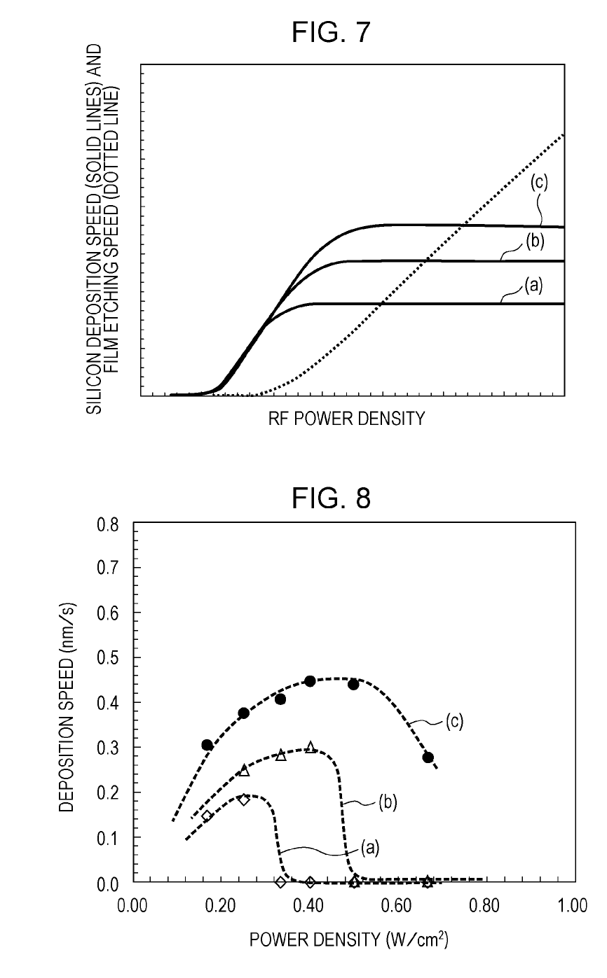

In the whole process of forming a microcrystalline silicon film by RF plasma CVD, it seems that two processes compete with each other: (A) SiH₄ is decomposed, and amorphous silicon and crystalline silicon accumulate on the substrate; (B) H₂ gas is decomposed and the resulting hydrogen radicals etch the silicon layer (primarily, its amorphous silicon portion) on the substrate. FIG. 7 schematically illustrates this in relation to the power density.

In FIG. 7, the horizontal axis represents the density of the electric power supplied by the power source 103, and the vertical axis represents the deposition speed of silicon and the etching speed of the film. The solid lines indicate the deposition speeds of microcrystalline silicon for dilution factors of (a) 1000, (b) 600, and (c) 300, and the dotted line indicates the speed of H₂ gas etching the formed film.

On the substrate, both amorphous silicon and crystalline silicon accumulate. At low power densities SiH₄ is not decomposed and no silicon layer is formed. As the power density is increased, however, SiH₄ is decomposed and a silicon layer is formed, and the deposition speed of silicon increases with increasing power density.

Once the power density reaches a particular level, the deposition speed plateaus and remains constant. This is because SiH₄ gas is almost completely decomposed and the supply of silicon reaches saturation. After this saturation state is reached, the amount of silicon deposited is determined by the concentration of SiH₄ gas; the saturation-state deposition speed increases with increasing concentration, or decreasing dilution factor, of SiH₄ gas.

On the other hand, the amount of hydrogen ions generated by the decomposition of H₂ gas monotonically increases with increasing power density because the supply of H₂ is practically unlimited. The etching speed in the etching process of the silicon layer therefore increases with increasing power density.

At low power densities, the amorphous silicon portion of the silicon layer is etched to a greater extent because of its weaker binding force. As a result, the amorphous portion is selectively removed from the formed silicon film, leaving a high-crystallinity and good-quality microcrystalline silicon film.

The actual speed of the microcrystalline silicon film growing on the substrate is the difference between the deposition speed in (A) and the etching speed in (B). FIG. 8 shows plots of deposition speed measurements. The curves (a), (b), and (c) in FIG. 8 correspond to the dilution factors (a), (b), and (c) in FIG. 7, respectively.

The results shown in FIG. 8 are qualitatively in line with the differences between the deposition speeds and the etching speeds in FIG. 7. The deposition speed first increases with increasing power density, but starts to decrease after a while. The peak speed increases with decreasing dilution factor. Silicon films having a high degree of crystallinity are obtained under conditions where amorphous silicon is etched and crystalline silicon is selectively deposited. Such conditions correspond to the regions surrounding the points of the peak deposition speeds in FIG. 8.

As mentioned in the results of the test (1), the condition (c), a dilution factor of 300, results in too large a threshold voltage drift. This is because the deposition speed of silicon is so high as illustrated in FIG. 8 that the degree of crystallinity of the resulting silicon film will be insufficient.

### 5. Optimum Film Formation Conditions

The following describes the optimum range of each film formation parameter.

### (i) Dilution Factor

At the initial stage of the formation of a microcrystalline silicon layer, very fine silicon crystal grains are formed on the substrate, and they serve as cores around which crystals grow. Small cores are likely to be etched and eliminated by hydrogen ions. When the dilution factor is low, however, the number of cores that remain unetched and grow is great because of the large number of cores formed. As a result, a microcrystalline silicon layer grows that shows a small crystal grain diameter and contains many grain boundaries.

Controlling the film formation speed to remain low allows silicon crystallites to grow with an increased crystal grain diameter and a reduced number of defects. A dilution factor equal to or higher than 600 ensures a sufficiently low film formation speed. Film formation under this condition gives the silicon film a high degree of crystallinity and a large crystal grain diameter as early as at the initial stage of formation. For a bottom-gate TFT, its performance is determined by the characteristics of the silicon film in the region from the interface with the gate insulating layer to the depth at which the channel is formed. Silicon crystallites having large diameters have only small numbers of grain boundaries and defects, both of which are potential causes of reduced electron mobility. The resulting TFT is thus highly resistant to electric current stress, or shows a small drift in threshold voltage.

In the test (3), two dilution factors, 1000 and 600, were assessed for the resulting threshold voltage drift with different power densities. Increasing the dilution factor resulted in a shift of the optimum power density range toward lower values. The curves (a) and (b) in FIG. 8 also made shifts toward lower power densities, supporting the inference that a ratio of the film formation speed to the power density close to its maximum results in a small threshold voltage drift.

The recommended range for dilution by 1000 times is on the low-power side with respect to that for dilution by 600 times. A possible reason for this is as follows. In order to form a film with fewer defects, the effect of hydrogen radicals is indispensable. When the dilution factor is low, therefore, a high power density is needed so that hydrogen radicals can have their activity enhanced. When the dilution factor is high, however, the effect of etching by hydrogen radicals is not negligible, and thus it is allowed to reduce the power.

When the dilution factor is high, the supply of hydrogen radicals is sufficient even with a low power. When the dilution factor is low, however, hydrogen radicals run out, leading to an increased amorphous silicon content, and the resistance of the TFT to electric current stress will be low.

As shown in FIG. 8, the lower the dilution factor, the higher the peak effective film formation speed. Although the results of the test (1) (FIG. 4) indicate that lower dilution factors resulted in greater threshold voltage drifts, this is because a low dilution factor causes the amorphous silicon content to be high.

### (ii) Pressure

As indicated by the results of the test (2) and shown in FIG. 5, any film formation pressure lower than 600 Pa results in a failure to form the silicon film. This is probably because any combination of a hydrogen dilution factor and a power density for the formation of a microcrystalline silicon film allows ions with long mean free paths to collide with the substrate, the silicon crystal cores formed at the early stage of silicon growth are removed by etching, and thus the growth of silicon is inhibited. Under a reduced pressure, the mean free paths of the ions in the plasma are extended, the ions collide with the substrate at increased speeds and more seriously damage and etch the microcrystalline silicon film formed, and the formation of the film is more strongly inhibited.

In other words, the failure to form the silicon film under a reduced gas pressure is because the accordingly reduced partial pressure of SiH₄ makes the etching effect of accelerated hydrogen ions dominant over the film formation process. Regarding the dilution factor, a smaller flow rate of SiH₄ (a higher dilution factor) led to a lower power threshold for the start of etching than that with a larger flow rate of SiH₄ (a lower dilution factor). The same trend was also observed for gas pressure.

In practice, the film formation pressure for the deposition of microcrystalline silicon can be equal to or higher than 600 Pa.

(iii) Power Density

As shown in FIG. 8, for a given hydrogen dilution factor, the effective film formation speed is high when the power density is in a particular range. The lower limit is the power density at which the decomposition rate of SiH₄ is sufficiently high, and the upper limit is the power density at which etching by H₂ becomes the main process by defeating the formation of the silicon film.

The film formation speed achieves its maximum when the process (A) reaches saturation. As can be seen from FIG. 8, the power density range in which a microcrystalline silicon film grows at a rate close to the highest film formation speed shifts toward lower values with increasing dilution factor.

The power density range in which TFTs were obtained with high resistance to electric current stress in the test (3) is described above. It can be seen that a microcrystalline silicon film is obtained with a small threshold voltage drift when the ratio of its formation speed to the power density is close to the maximum.

A low power density leads to a high amorphous silicon content, thereby resulting in a large threshold voltage drift. The lower limit of power density is determined from the conditions under which amorphous silicon deposited on the substrate is efficiently etched by hydrogen ions and the growth of crystalline silicon is promoted. A power density smaller than the lower limit causes inadequate decomposition of hydrogen and thus results in the deposition of amorphous silicon being dominant.

Even with varying dilution factors and pressures, the fact remains that the lower limit of power density is the threshold below which the etching of amorphous silicon by hydrogen ions is dominant. When the dilution factor is halved (while the pressure is maintained), the flow rate of SiH₄ gas is doubled, the formation speed of the amorphous silicon layer is doubled, and thus the power density required to decompose H₂ in an amount enough to etch the amorphous silicon layer is doubled. Although halving the dilution factor involves halving the flow rate of H₂ gas, the system contains ample H₂ gas and its supply is practically unlimited because the dilution factor is originally as large as several hundred times. Therefore, the ionization rate of H₂ is independent of the supply of H₂ gas and is determined solely by the power density.

Likewise, when the pressure is doubled (while the dilution factor is maintained), the flow rate of SiH₄ gas is doubled, and the power density requirement is doubled. In summary, the lower limit of the recommended range of power density is inversely proportional to the dilution factor and is proportional to the pressure.

Too high a power density, however, results in silicon not being deposited at all. This is because the excessive amount of hydrogen ions causes the etching process to involve not only amorphous silicon but also crystalline silicon. When the amount of hydrogen ions is small, amorphous silicon is selectively etched in accordance with the ratio of etching speed between amorphous silicon and crystalline silicon. As the hydrogen ion concentration is increased, however, the etching speed of crystalline silicon is increased and exceeds the deposition speed, resulting in a complete failure to form the film.

In this way, the upper limit of power density is determined from the conditions under which the nonselective etching of the formed film by hydrogen radicals is dominant.

How the deposition and etching processes that occur near the upper limit of power density are influenced by changes in dilution factor and pressure can be described as follows. First, when the dilution factor is halved while the pressure is maintained, the flow rate of SiH₄ gas is doubled, and the deposition speed of silicon is also doubled. As a result, the power density required to etch the silicon film is also doubled. Likewise, when the pressure is doubled while the dilution factor is maintained, the formation speed of the silicon film is doubled, and the power density requirement is also doubled. Thus, if the dilution factor is halved or the pressure is doubled and if the power density is doubled at the same time, then the formed film is completely etched by hydrogen ions (or hydrogen radicals). This is the situation that occurs near the upper limit of power density.

### 6. Conclusion

The above discussions (i) to (iii) conclude that a microcrystalline silicon film can be obtained with a sufficiently small threshold voltage drift by using an appropriate power density determined by the pressure and the dilution factor. More specifically, the power density is specified in such a manner that the value defined by the following formula should fall within a particular range: Power density (W/cm²)*Dilution factor/Pressure(Pa). As demonstrated by the results of the test (3), the range this value should be in is 0.083 to 0.222, both inclusive.

Furthermore, a dilution factor equal to or higher than 600 provides the silicon film with an increased crystal grain diameter.

The pressure should be high enough that molecules with long mean free paths will not etch the substrate by colliding with it. More specifically, the pressure is set to 600 Pa or higher.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-057728 filed Mar. 15, 2010, No. 2011-029998 filed Feb. 15, 2011, and No. 2011-159076 filed Jul. 20, 2011, which are hereby incorporated by reference herein in their entirety.

What is claimed is:

1. A method for manufacturing a silicon semiconductor device including steps of:
forming a gate electrode and a gate insulating layer containing silicon nitride on a substrate in this order;
forming a silicon-oxide-containing layer on the gate insulating layer;
forming a silicon layer containing crystalline silicon and amorphous silicon by chemical vapour deposition on the silicon-oxide-containing layer; and
forming a contact layer and source and drain electrodes on the silicon layer in this order,
wherein the chemical vapour deposition in the step of forming the silicon layer is performed under a condition of
a power density Pw of the radiofrequency power being in the range of 0.1 to 0.8 W/cm²,
a pressure P of a gas mixture in a chemical vapour deposition chamber being in the range of 200 to 1066 Pa and
a dilution factor D of a silicon-containing raw material gas with a hydrogen gas being in the range of 100 to 3000.

2. The method for manufacturing a silicon semiconductor device according to claim 1, wherein in the step of forming a silicon-oxide-containing layer, the silicon-oxide-containing layer is formed by exposing the gate insulating layer to water vapour, oxygen, or an oxygen-containing mixed atmosphere.

3. The method for manufacturing a silicon semiconductor device according to claim 1, wherein
in the step of forming a silicon-oxide-containing layer, the silicon-oxide-containing layer is formed by chemical vapour deposition.

4. The method for manufacturing a silicon semiconductor device according to claim 1, wherein the chemical vapour deposition in the step of forming the silicon layer is performed under a condition of the pressure P of gases being 600 Pa or higher, the dilution factor D being 600 or higher and the power density Pw of the radiofrequency electric field being such that Pw(W/cm²)*D/P(Pa) is within a range of 0.083 to 0.222.

5. A method for manufacturing a silicon semiconductor device including steps of:
forming a gate electrode and a gate insulating layer containing silicon nitride on a substrate in this order;
forming a silicon layer containing crystalline silicon and amorphous silicon by chemical vapour deposition; and
forming a contact layer and source and drain electrodes on the silicon layer in this order,
wherein the chemical vapour deposition in the step of forming a silicon layer is performed by steps of:
diluting a silicon-containing raw material gas with a hydrogen gas by a factor equal to or larger than 600;
applying radiofrequency power to a gas mixture of the diluted raw material gas and hydrogen gas to induce electric discharge;
depositing silicon out of the raw material gas decomposed by the electric discharge onto a substrate; and
controlling a pressure of the gas mixture to be equal to or higher than 600 Pa,
wherein the power density Pw(W/cm²) of the radiofrequency power is specified in such a manner that the value Pw(W/cm²)*D/P(Pa) should fall within the range of 0.083 to 0.222, both inclusive, where D represents the dilution factor of the raw material gas with the hydrogen gas and P (Pa) represents the pressure of the gas mixture.

6. The method for manufacturing a semiconductor device according to claim 5, further including a step of forming a silicon-oxide-containing layer before the step of forming a silicon layer.

7. The method for manufacturing a semiconductor device according to claim 6, wherein the silicon-oxide-containing layer is formed by exposing the surface of the gate insulating film to an oxygen atmosphere.
